(19) United States
(12) Patent Application Publication
(10) Pub. No.: US 2010/0062610 A1
(43) Pub. Date: Mar. 11, 2010

(54) METHOD OF REGULATING THE TITRATION OF A SOLUTION, DEVICE FOR CONTROLLING SAID REGULATION AND SYSTEM COMPRISING SUCH A DEVICE

(75) Inventors: Hervé E. DULPHY, Jarrie (FR); Christophe MARTIN, Aix en Provence (FR)

Correspondence Address: AIR LIQUIDE;Intellectual Property, 2700 POST OAK BOULEVARD, SUITE 1800, HOUSTON, TX, 77056, US

(73) Assignees: L'Air Liquide Societe Anonyme a Directoire et Conseil de Surveillance pour l'Etude et; I'Exploitation des..., Paris (FR)

(21) Appl. No.: 12/620,449

(22) Filed: Nov. 17, 2009

Related U.S. Application Data
(62) Division of application No. 10/498,256, filed on Dec. 6, 2004.

(30) Foreign Application Priority Data
Dec. 10, 2001 (FR) 0115932

(51) Int. Cl. H01L 21/302

(52) U.S. Cl. 438/745; 156/345.17; 257/E21.214

(57) ABSTRACT

Method for regulating the titration of a solution, in which a predetermined amount of a product contained in the solution is added to the solution according to a time interval, called the addition interval, which is proportional to the product of the time degradation coefficient D of the product in solution and the total volume Vt of the solution at the time of the addition.

### CROSS-REFERENCE TO RELATED APPLICATIONS

This application is a divisional application of prior application Ser. No. 10/498,256, filed Dec. 6, 2004, which is a national stage entry under 21 USC §371 of PCT/FR02/04250, filed Dec. 10, 2002, which claims priority to French application 01/15932, filed Dec. 10, 2001, the entire contents of which are incorporated herein by reference.

### BACKGROUND

The invention relates to the field of chemical regulation, in particular the chemical regulation of slurries or compounds of material in suspension and/or of various chemical products (acids, bases, organic compounds) in solution.

Such products are used, for example, in the semiconductor industry where they serve in the chemical-mechanical polishing of semiconductor wafers or substrates.

Some of these slurries or these suspensions use a compound whose concentration decreases over time, for example by decomposition by chemical reaction (this is the case with H₂O₂) or by evaporation (NH₄OH).

It is therefore necessary in this case to regulate the titre of chemical product(s) (H₂O₂, NH₄OH) of this slurry.

The current techniques for regulating slurries employ a buffer tank 4 and a mixing tank 2, as illustrated schematically in FIG. 1. The products leaving the buffer tank are then taken into a delivery system 8 and are used in operations such as the abovementioned polishing operations.

The operation of the tanks 2 and 4 may be described in the case of H₂O₂.

The tanks 2, 4 operate between a high level (Levelmax) and a hysteresis level which triggers the filling.

They are regulated in terms of H₂O₂ titre (% wt).

The filling of the buffer tank 4 takes place when the hysteresis level is reached, with slurry that comes from the mixing tank 2.

The slurry delivery system is composed of a continuous circulation loop, as described in U.S. Pat. No. 6,125,876, which prevents the slurry from stagnating in the network and makes it possible to regulate the pressure to the equipment by means of a pressure sensor. The feed and the return in this loop are at the base of the buffer tank 4.

The mixing tank 2 is fed with “pure” slurry and with hydrogen peroxide (for example 31% H₂O₂). It is regulated in terms of titre before each transfer of product into the buffer tank 4.

The hydrogen peroxide titre is regulated by provision of 31 wt % H₂O₂.

The titration operations carried out on the buffer tank 4 use a potentiometric titrator 7 or sometimes two titrators.

The titrator takes a measurement of the titre periodically (that can be paramaterized). Its operation can be described in conjunction with FIG. 2. This figure shows three titration levels, namely a high level (maximum value), a low level (minimum value) and a setpoint value to be reached.

If the titre is below the setpoint (Case 1 in FIG. 1), a readjustment is made by adding the lacking amount of H₂O₂.

Should the titre be above the setpoint (Cases 2 and 4 in FIG. 1), no regulating action is taken.

Should the titre be above the maximum value (Case 3 in FIG. 1), a second check is carried out. If this confirms that the titre is too high, an alarm is triggered. If the titre proves to be normal after the second check, no regulating action is taken.

Should the titre be below the minimum value (Case 5 in FIG. 1), a second check is carried out. If this confirms that the titre is too low, an alarm is triggered. If the titre proves to be normal after the second check, no regulating action is taken.

Triggering an alarm results in the delivery system 8, and therefore the production being stopped.

Moreover, each titrator employs, in particular, elements such as electrodes and capillaries.

The measurement taken furthermore depends on the titration reactants and on any drift of the electrodes or capillaries. There are therefore many sources of error.

Furthermore each titrator represents in general an overall cost of about 10% of the overall cost of the production plant on which it is mounted.

Each titrator is also a source of breakdowns and therefore entails substantial operating costs.

A problem that arises is to find a novel system of regulating the titration of suspensions, especially within the context of the fabrication of production units for semiconductor wafers or substrates, which is free of the abovementioned drawbacks.

### SUMMARY

The invention provides a method for regulating the titration, or titre, of a solution, in which a predetermined amount of a product contained in the solution is added to the solution according to a time interval proportional to the product of the time degradation coefficient D of said product in solution and the total volume Vt of the solution at the time of the addition.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 illustrates a known regulating system;

FIG. 2 illustrates various states of filling of a tank;

FIG. 3 illustrates a regulating system according to the invention;

FIG. 4 illustrates decomposition curves for a product in a tank; and

FIG. 5 illustrates a device for injecting a product, according to the invention.

### DESCRIPTION OF PREFERRED EMBODIMENTS

The invention provides a method for regulating the titration, or titre, of a solution, in which a predetermined amount of a product contained in the solution is added to the solution according to a time interval proportional to the product of the time degradation coefficient D of said product in solution and the total volume Vt of the solution at the time of the addition.

The invention provides a method for regulating the titre of a solution, in which a predetermined amount of a product contained in the solution is added to the solution according to a time interval proportional to the product of the delayral degradation coefficient D of the product in solution and the total volume Vt of the solution at the time of the addition.

This method depends only on the calculation of the addition interval, which depends only on the measurement of the total volume of the solution. This measurement may be performed in an analogue manner.

The method according to the invention entails a much lower cost than the method employing a titrator, and is also not a source of breakdowns, unlike known titrators. It does not employ electrodes that can drift and it does not depend on titration reactants either.

After each addition of product, the time interval before the next injection may be calculated.

Thus, it is possible, after a certain period of time less than the addition interval, to measure the total volume of the solution. If this volume has not varied, the same predetermined amount of product is again injected or added. If the total volume has decreased, a new addition time is calculated according to the same calculation rule.

The invention also relates to a device for controlling the regulation of the titration of a solution, this solution containing a product, comprising means for controlling the injection of a predetermined amount of said product into said solution according to a time interval known as the addition interval, proportional to the product of the time degradation coefficient D of the product in solution and the total volume Vt of the solution at the time of the addition.

The invention also relates to a system for regulating the titre of a solution, comprising a device as above, and means for determining a fill volume in a container containing the solution. These means for determining a fill volume may be analogue means.

Such a regulating system may furthermore include an electrode titration device.

The invention also relates to a system for producing a chemical solution, comprising:
a regulating system as above;
means for delivering the solution.

According to the invention, a system for producing semiconductor substrates includes a unit for polishing the substrates and a system for producing a chemical polishing solution as above.

FIG. 3 shows a diagram of a regulating system according to the invention. This diagram, like that in FIG. 1, relates to the regulation of slurries (or compounds of material in suspension and/or various chemical products in a solution) in a semiconductor wafer or substrate production unit. The references 2, 4, 6 and 8 denote elements identical or equivalent to those of FIG. 1.

Table 1 below summarizes the abbreviations used in the present description, illustrated (non-restrictingly) with a few numerical values in the right-hand column.

Indices:
i: initial
add: added
meas: measured
slur: slurry
m: slurry/hydrogen peroxide mixture
mix: mixing tank
targ: target or desired value
pure: undiluted

TABLE 1

| | | Unit | | Value | |
|---|---|---|---|---|---|
| Parameters | Definition | Values | Type | Example | |
| Deg_{buffer} | Amount of H₂O₂ | % H₂O₂/ | Measured | 0.189 | |
| | degradation in the | day | value on the | % H₂O₂/ | |
| | slurry in the buffer tank | | curve | day | |
| Degₘᵢₓ | Amount of degradation | % H₂O₂/ | Measured | 0.189 | |
| | of H₂O₂ in the slurry in | day | value on the | % H₂O₂/ | |
| | the mixing tank | | curve | day | |
| Diffₘᵢₓ | Maximum difference for | % H₂O₂ | Calculation | 0.06% | |
| | the mixing tank | | | | |
| | between the last H₂O₂ | | | | |
| | titre analysis and the | | | | |
| | new one | | | | |
| K/Kₘᵢₓ/K_{buffer} | Coefficient of addition | % H₂O₂ | Calculation | 0.16% | |
| | of the 100 ml dose of | | | | |
| | H₂O₂ in the slurry for a | | | | |
| | mixing tank/buffer tank | | | | |
| M_{H}₂0₂,add | Mass of H₂O₂ to be | kg | Calculation | 523 | kg |
| | added to the tank | | | | |
| M_{slurry,i} | Mass of slurry in the | kg | Measurement | 1123 | kg |
| | tank before analysis | | | | |
| M_{added slurry} | Mass of slurry to be | kg | Calculation | 523 | kg |
| | added to the tank | | | | |
| Mₜₐₙₖ | Maximum weight of | kg | Parameters | 1360 | kg |
| | slurry in the tank | | | | |
| Levelₘₐₓ | Maximum permissible | % of | Parameters | 95% | |
| | level in the tank | filling | | | |
| Level_{working} | Permissible working | % of | Parameters | 90% | |
| | level in the tank | filling | | | |
| Level_{hyst} | Range of variation in | % of | Parameters | 35% | |
| | the mixing tank/buffer | filling | | | |
| | tank | | | | |
| Levelₘᵢₙ | Minimum permissible | % of | Parameters | 60% | |
| | level in the tank | filling | | | |
| Levelₜₐₙₖ | “Current” level in the | % of | Measurement | 68% | |
| | mixing tank | filling | | | |
| Level_{slurry} | Level of slurry to be | % of | Calculation | 10% | |
| | added to the tank | filling | | | |
| Level_{H}₂0₂ | Level of H₂O₂ to be | % of | Calculation | 1% | |
| | added to the tank | filling | | | |
| N_{buffer} | Stirring power number | number | Parameters | −50_0 | |
| | in the buffer tank | | | | |
| Nₘᵢₓ | Stirring power number | number | Parameters | −50_0 | |
| | in the mixing tank | | | | |
| N_{titration, mix} | Successive titration | number | Parameters | 1-4 | |
| | number of the mixing | | | | |
| | tank during an off-spec | | | | |
| | analysis before a fault | | | | |
| | is triggered | | | | |
| Slurryₘ | Mixing of on-spec H₂O₂ | | | | |
| | and slurry | | | | |
| Amount_{fill} | % Level in the tank | % | Measurement | 65.5% | |
| Time_{inter-analysis} | Time before the new | day | System | 2 | day |
| | analysis of the mixing | | value | | |
| | tank after an off-spec | | | | |
| | titre | | | | |
| Time_{additions/analysis} | Determination of the | minutes | Parameters | 40 | min |
| | time between the end of | | | | |
| | the H₂O₂ additions and | | | | |
| | the analysis of the in- | | | | |
| | tank H₂O₂ titre | | | | |
| Time_{buffer inject} | Time between each | minutes | System | 35 | min |
| Time_{mix inject} | new injection of H₂O₂ | | value | | |
| | into the tank for the | | | | |
| | doses added. | | | | |
| TimeIjectₘᵢₓ | Time since last titration | 0-21 | System | Existent | |
| | of the mixing tank | days | value | | |
| Titre_{H}₂0₂,pure | Desired (target) H₂0₂ | wt % | Parameters | 4.2% | |
| Titre_{H}₂0₂,targ | titre in the tank | | | | |
| Titre_{H}₂0₂,i | H₂0₂ titre to be used for | wt % | Parameters | 31% | |
| | the additions | | | | |
| Titre_{H}₂0₂,mess | H₂0₂ titre measured in | wt % | Parameters | 4.18% | |
| | the tank | | | | |
| Titre_{pure H}₂0₂ | H₂O₂ titre used in pure | | | | |
| | form, undiluted | | | | |
| | Minimum value of the | wt % | Parameters | 4.15% | |
| | desired H₂0₂ titre in the | | | | |
| | tank | | | | |
| Titreₘᵢₙ | Maximum value of the | wt % | Parameters | 4.25% | |
| | desired H₂O₂ titre in the | | | | |
| | tank | | | | |
| Titreₘₐₓ | Precise volume of the | milli- | Parameters | 104 | ml |
| | 100 ml H₂O₂ injection | litres | | | |
| | dose | | | | |
| V1 | Precise volume of the | milli- | Parameters | 875 | ml |
| | 900 ml H₂O₂ injection | litres | | | |
| | dose | | | | |
| V2 | Precise volume of the | milli- | Parameters | 9012 | ml |
| | 9000 ml H₂O₂ injection | litres | | | |
| | dose | | | | |
| V3 | Volume of Slurryₘ in the | % fill | System | 78% | |
| | buffer tank | | value | | |
| V_{buffer} | Volume of the tank- | | | | |
| | volume of slurry | | | | |
| V_{total buffer} | | | | | |
| Vol_{H}₂0₂,i | Volume of concentrated | litres | Calculation | 65 | litres |
| | H₂O₂ to be added to the | | | | |
| | mixing tank | | | | |
| Vol_{added slurry} | Volume of slurry to be | litres | Calculation | 261 | litres |
| | added to the mixing | | | | |
| | tank | | | | |
| ρH₂0₂i | Density of H₂O₂ to be | kg/m³ | Fixed value | 1.11 | kg/m³ |
| | used for the additions | | | | |
| ρ_{slurry} | Density of the slurry | kg/m³ | Fixed value | 1.043 | kg/m³ |

| | | | | |
|---|---|---|---|---|
| Kₘᵢₓ | Theoretical degradation | % H₂O₂/D | Parameters | new |
| | per day of the H₂O₂ titre | 0-0.4 | | |
| | in the mixing tank for a | | | |
| | full tank | | | |

The buffer tank 4 is regulated as follows.

An injection of a predetermined volume (for example, 100 ml) is programmed at a time interval that depends on several parameters:

1—on K, coefficient of addition of the 100 ml of H₂O₂ dose for the slurry:
K depends on:
the maximum volume in the buffer tank,
the precise volume of the H₂O₂ dose to be added and in principle, on the stirring rate in the tank;

2—on the volume in the tank in question at the time of the addition, i.e. Vtotal-buffer=Vtbuffer×Factorfill;

3—on the daily H₂O₂ degradation coefficient Degbuffer in the tank.

As regards the buffer tank, the time between two injections is given by: Timeinject buffer=K×Degbuffer×Vbuffer.

A controller 10 (for example, a programmed microcontroller) carries out the calculation, after each H₂O₂ injection, of the delay before the next injection. This controller comprises means for storing the various data used for the calculation and a microprocessor that carries out the desired calculations and manages and controls the various product injections.

Moreover, a measurement of the volume in the tank 4 is made, for example by conventional analogue means.

After the calculated delay, the controller performs a test on the new measured volume in the tank:

if there is no change in level (for example within ±4%), the predetermined dose is then injected;

if there is a decrease in level (product was consumed since the last addition), the controller recalculates the injection delay according to the new volume. The time already elapsed is subtracted from the new delay so as to determine at what moment the new addition will be made; and

upon filling the buffer tank, the addition operation is initialized at “time=0” and the calculation of the time is repeated according to the new level (no addition at t=0).

In fact, K depends on the specifications of the tank (height, diameter, volume) and on the stirring rate, whereas the degradation coefficient Deg itself depends on K and on the volume ratio of energy dissipated in the slurry (in W/m3).

The coefficient K and the degradation curve for a given tank are determined in the following manner.

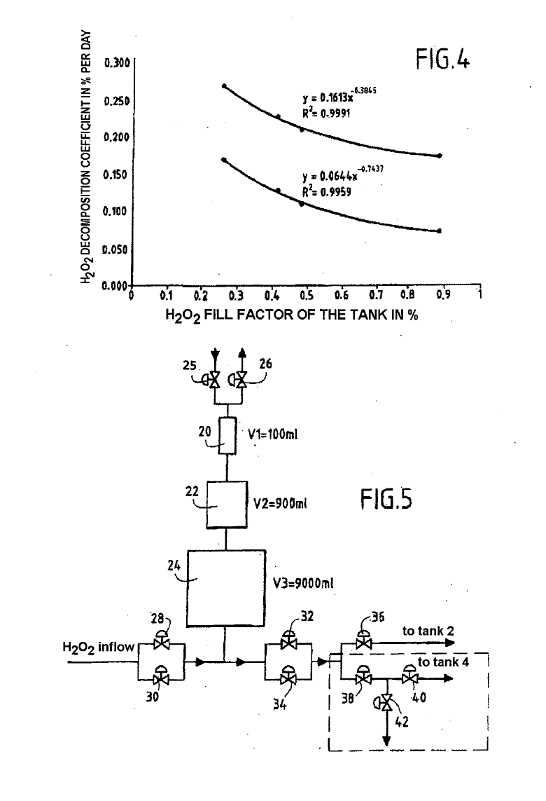

The H₂O₂ degradation measurements are made as a function of the level in the tank. A curve of the type of those illustrated in FIG. 4 is then obtained.

The method used is as follows:
fill the tank to 90% with a slurry mixture whose H₂O₂ titre is known (about 4.2%);
wait 24 hours and then measure the titre again;
purge the tank in order to vary the level and reset the mixture to the titre (about 4.2%);
wait 24 hours and then measure the titre again;
repeat several times in order to obtain enough points; and
deduce therefrom decomposition curve for the H₂O₂ in the tank as a function of its fill level.

The coefficient K is the coefficient of the exponential function found. Thus, in FIG. 4, one curve has as coefficient K=0.1613 and the other K=0.0644.

The curve giving the variations in the degradation coefficient D as a function of the fill factor is identical or similar to that expressing the variations in the degradation coefficient D as a function of a stirring rate for a fixed level in the tank. This is because, in one case the energy (W) is varied, and in the other case the volume (m³) is varied. However, these two variables are of the same order of magnitude. If both the stirring rate and the level in the tank are varied at the same time, a representation in the form of isolevels is obtained and therefore one with several curves. In all cases, these variables do not depend on the H₂O₂ dose.

In order to add a further safety factor to the system described above, it is also possible to add a measurement by a conventional titrator or an electrode titrator.

The H₂O₂ addition is then always made as described above, but regular analysis by the titrator allows the measurement to be validated.

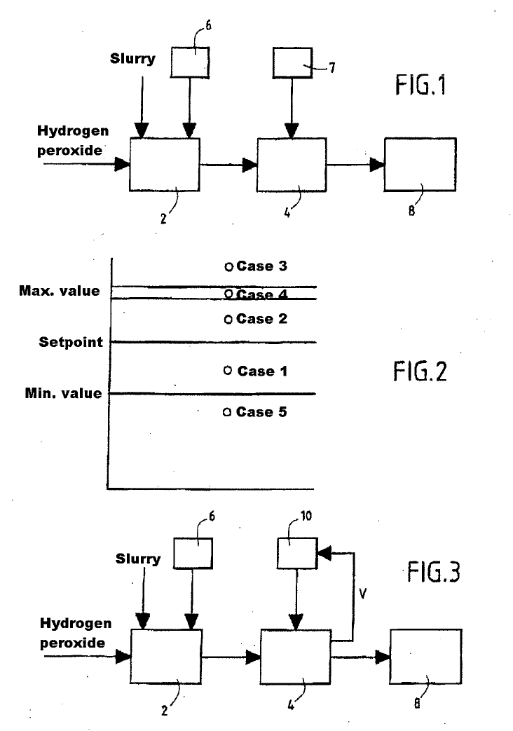

The operation is then as below, the various cases being those in FIG. 2.

Case 1: should the titre be below the setpoint, readjustment as in the mode of regulation by the titrator (already described above in the introduction).

Case 2: should the titre be above the setpoint, no action.

Case 3: should the titre be above the maximum value, a second measurement is taken:

if this confirms that the titre is too high, an alarm is triggered, and additions are stopped;

if at the second measurement the titre appears normal, no action is undertaken.

Case 4: should the titre be similar to the maximum value (for example greater than the maximum value—0.01%), a second measurement is taken:

if this confirms that the titre is too high, an alarm is triggered and additions are stopped;

if at the second measurement the titre appears normal, no action is undertaken.

Case 5: should the titre be below the minimum value, a second measurement is taken:

if this confirms that the titre is too low, an alarm is triggered and the titre is adjusted;

if at the second measurement the titre appears normal, no action is undertaken.

The foregoing description relates to the buffer tank 4.

The mixing tank 2 is regulated in terms of H₂O₂ titre (wt %) before each filling of the buffer tank and in terms of fill (%) after each transfer to the buffer tank 4.

The filling of this tank 2 and its setting to the titre take place in the following manner.

First, a mixture is prepared. The level in the tank 2 is maintained between:

a level Levelmin=Levelmax−Levelhyst (F1)

and

a level Levelworking=Levelmax×0.95 (F2),

where 0.95 is a safety factor allowing the H₂O₂ titre to be adjusted without the high level in the mixing tank being exceeded.

The level in the tank decreases as Slurrymix is transferred from the mixing tank 2 to the buffer tank 4. The level is reset after each fill if the final level in the mixing tank 2 reaches the value Levelmin.

The product in the mixing tank 2 is prepared with Slurryp (“pure” slurry with no H₂O₂) and 31 wt % hydrogen peroxide.

This preparation is carried out so as to obtain a level in the mixing tank such that:

Levelmax×0.95=(Levelinitial+Levelslurry+Level H₂O₂) (F3)

The H₂O₂ to be added by filling the mixing tank 2 is calculated using the following formula (F4):

Titre H₂O₂=Vol H₂O₂, i×ρH₂O₂, i×titreH₂O₂,i/(Vol H₂O₂,i×ρH₂O₂,i+Voladded slurry×ρslurry).

The following formula for calculating the hydrogen peroxide to be added to the mixing tank is then obtained:

MH₂O₂,add=Mslurry,I×TitreH₂O₂,targ/(TitreH₂O₂,i−TitreH₂O₂,targ) (F5).

In practice, the various filling steps are carried out in the following manner:
1) the line for filling the mixing tank with the slurry is firstly rinsed (delay);
2) then the tank is filled with the slurry: Madded slurry according to the formula (F6):

Mslurry,add=Mtank×(Levelmax×0.95−Levelinitial)×Titre H₂O₂,targ/(Titre H₂O₂,i−Titre H₂O₂,targ) (F6);
3) next, the line for filling the mixing tank with DIW is rinsed (delay);
4) the valve for filling the mixing tank is then rinsed with DIW (delay);
5) next, the tank is filled with H₂O₂ (M H₂O₂,add) where:

MH₂O₂,add=Mtank×(Levelmax×0.95−Levelinitial×Titrepure H₂O₂/Titre H₂O₂) (F7);
6) waiting while the mixing tank homogenizes (waiting time=Timeadditions/analysis);
7) next, the mixing tank is analysed and its titre obtained: Titre H₂O₂ meas

if Titremin≦Titre H₂O₂ meas≦Titremax, validation of the mixing tank—the procedure passes to stage 10)

if Titre H₂O₂meas≦Titremax:
carry out another analysis for confirmation (Ntitration, mix),
if confirmation, an alarm is triggered and a request for operator intervention is generated,

if Titre H₂O₂ meas<Titremin, a titre is adjusted and then the procedure passes to stage 8):
check that TitreH₂O₂,targ−TitreH₂O₂,meas<Diffmix, (where Diffmix is the maximum difference in the case of the mixing tank between the last determination of the H₂O₂ titre and the new one),
carry out another determination for confirmation (Ntitration, mix);
8) the titre is then adjusted, the adjustment steps being the following:

calculation of the H₂O₂ volume to be added using formula (F8),

H₂O₂ addition for adjustment (as a result of the decrease in the H₂O₂ titre) and

waiting for homogenization of the mixing tank (waiting time=Timeadditions/analysis);
9) the mixing tank is analysed in order to confirm that the titre is within specification; and
10) there is then a wait for a demand to fill the buffer tank.

The titre of the tank 2 is regulated in the following manner. In fact, the same calculating method is used to calculate the mass of hydrogen peroxide to be added to the mixing tank 2 in order to regulate the titre:

MH₂O₂,add=Mslurry,i×(TitreH₂O₂,targ−TitreH₂O₂,meas)/(TitreH₂O₂,i−TitreH₂O₂,targ) (F8)

The successive steps are then the following:
1) Analysis of the mixing tank. Hence the titre obtained: Titre H₂O₂,targ

if Titremin≦Titre H₂O₂,meas≦Titremax, then validation of the mixing tank, and the procedure passes to step 10)

if, Titre H₂O₂,meas>Titremax:
carry out another analysis for confirmation (Ntitration,mix)
if confirmation, alarm and request intervention by an operator,

if Titre H₂O₂,meas<Titremin, the titre is adjusted and the procedure passes to step 8):
then check that Titre H₂O₂,targ−Titre H₂O₂,meas<Diffmix (where Diffmix is the maximum difference for the mixing tank between the last determination of the H₂O₂ titre and the new one),
carry out another analysis for confirmation (Ntitration, mix);
2) adjustment of the titre:

calculation of the H₂O₂ volume to be added using formula (F8),

H₂O₂ addition for adjustment (as a result of the decrease in the H₂O₂ titre),

waiting for the mixing tank to homogenize (waiting time=Timeadditions/analysis);
3) analysis of the mixing tank in order to confirm that the titre is within specification; and
4) waiting for a request to fill the buffer tank.

The buffer tank 4 is, for its part, constantly regulated in terms of H₂O₂ titre (wt %) and in terms of filling (%).

The level in the tank is maintained between:

a level: Levelmin,i=Levelmax−Levelhyst (F1)

and

a level: Levelworking=Levelmax×0.95 (F2)

where 0.95 is a safety factor that allows the H₂O₂ titre to be adjusted without the high level being exceeded in the mixing tank.

The level in the tank 4 decreases as product is consumed by the equipment.

It is then filled with Slurrym which comes from the mixing tank 2, as soon as its level goes below the level Levelhyst.

The filling steps are carried out as follows:
1) request to fill the mixing tank 2;
2)—mixing tank 2 not ready: on standby
mixing tank 2 ready: proceed to step 3);
3) rinsing of the line for filling the buffer tank with Slurrym and then filling of the buffer tank with Slurrym until the level Levelmax×0.95;
4) rinsing of the line for filling the mixing tank with DIW (delay).

The formula for regulating the titre in the buffer tank 4, making it possible to calculate the amount of hydrogen peroxide to be added, is the same as in the mixing tank:

MH₂O₂,add=Mslurry,i×(TitreH₂O₂,targ−TitreH₂O₂,meas)/(TitreH₂O₂,i−TitreH₂O₂,targ) (F8).

The hydrogen peroxide is added to the buffer tank via metering tanks on the product return.

A valve system called a “block and bleed” system is used for adding hydrogen peroxide while preserving the tank from any in-line leaks which would add hydrogen peroxide to the buffer tank when filling the mixing tank with peroxide.

The titre is regulated using the method already explained above.

As regards the titration of the mixing tank 2, this takes place in the following manner. The permissible value with respect to the difference between two determinations carried out on the mixing tank depends on a parameter Degmix (H₂O₂ degradation coefficient).

The H₂O₂ titre degradation coefficient in the mixing tank 2 itself depends on the stirring in the tank and on the level in the tank.

This is because although the stirring rate in the tank is constant the energy dissipated per unit volume can vary. Consequently, the rate of degradation in the tank depends on its slurry level.

The degradation curve is therefore a power curve (typical of stirring phenomena).

It is therefore possible to estimate the H₂O₂ titre reduction in the tank between two determinations:
mixing tank difference in %=Diffmix mixing tank degradation in %/per day=Degmix where Degmix=Kmix×Levelmix tank;
time since last titration in days=timemix inject Diffmix=Degmix×Timemix inject.

If a determination of the titre indicates that the titre is too low in the mixing tank 2 (Titre H₂O₂,targ−Titre H₂O₂,meas<Diffmix), the system triggers a titre readjustment by H₂O₂ addition.

If a determination indicates that the titre is too high in the mixing tank, the system triggers, after successive confirmation, a “mixing tank titre too high” alarm which disappears when the titre becomes normal again.

Another determination carried out on the tank is performed after a Timeinter-analysis which is calculated as follows:

Timeinter-analysis=Diffmix/Degmix.

If there is a titration alarm:

During determination of the titre, if the value is such that Titre H₂O₂,targ−Titre H₂O₂ meas>Diffmix, the system triggers (after Ntitration,mix successive confirmations) an alarm and requests the intervention by an operator.

A titration error with regard to the mixing tank must not stop the system—it must only generate a minor defect (for H hours, a parameter that can be modified) and then a major defect after H hours if there has been no intervention by the operator.

The H₂O₂ additions are made using a system of containers which is filled with product, with venting to atmospheric pressure, followed by pressurization in order to fill one of the two tanks (buffer tank or mixing tank).

This arrangement illustrated in FIG. 5 consists of 3 successive containers 20, 22, 24 of volume known to within one millilitre:
a first container 20 of volume about V1=100 ml, known precisely; known precisely;
a second container 22 of volume about V2=900 ml,
a third container 24 of volume about V3=9000 ml, known precisely.

Example of use in the case of an 11.3 volume of H₂O₂
filling of the containers;
draining down to the 10 000 millilitre level (V1+V2+V3);
filling of the containers; draining down to the 1000 millilitre level (V1+V2);
filling of the containers; draining down to the 100 millilitre level (V1);
filling of the containers;
draining down to the 100 millilitre level (V1);
filling of the containers; and
draining down to the 100 millilitre level (V1);

In fact, the volumes V1, V2 and V3 are not precise multiples of one hundred millilitres—the program of the controller 10 takes this into account when calculating the doses to be added.

In FIG. 5, the references 25 and 26 denote valves on a pressurization line and a venting line, respectively. The valves 32 and 34 are valves for rapid addition and slow addition respectively, (via a calibrated orifice). The product is then sent into the tank 2 (valve 36) or the tank 4 (via valves 38 and 40) or else to a draining line via a valve 42.

The regulating method according to the invention applies especially to controlling the titre of a chemical solution for polishing semiconductor substrates.

A regulating system according to the invention therefore delivers a polishing product to delivery means. This product is then delivered to a substrate polishing unit.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above.

What is claimed is:

1. A process for polishing semiconductor substrates comprising:
a) providing said semiconductor substrates;
b) preparing a solution, wherein a method of regulating a titration of said solution comprises adding a predetermined amount of a product to the solution according to an addition interval, wherein said addition interval is a time interval proportional to a product of a time degradation coefficient D of said product in solution and a total volume Vt of the solution at a time of the addition; and
c) polishing said semiconductor substrates with said solution.

2. A device for controlling the regulation of a titration of a solution, comprising:
a) a product; and
b) a means for controlling an injection of a predetermined amount of said product into said solution according to an addition interval, wherein the addition interval is a time interval proportional to a product of a time degradation coefficient D of said product in solution and a total volume Vt of the solution at the time of the addition.

3. The device of claim 2, further comprising a means for determining the time interval before a next injection after each injection of product.

4. A system for regulating a titration of a solution, which comprises a device according to claim 2 and a means for determining a fill volume in a container containing said solution.

5. The system of claim 4, wherein the means for determining said fill volume are analog means.

6. The system of claim 4, further comprising an electrode titration device.

7. A system for producing a solution, comprising:
a) a system for regulating a titration of a solution, which comprises a device comprising:
i) a product, and
ii) a means for controlling an injection of a predetermined amount of said product into said solution according to an addition interval, wherein the addition interval is a time interval proportional to a product of a time degradation coefficient D of said product in solution and a total volume Vt of the solution at the time of the addition; and
b) a means for delivering said solution.

8. A system for producing semiconductor substrates, comprising:
a) a unit for polishing said substrates, and
b) a system for producing a chemical polishing solution, comprising a system for regulating a titration of said solution, which comprises a device comprising:
i) a product, and
ii) a means for controlling an injection of a predetermined amount of said product into said solution according to an addition interval, wherein the addition interval is a time interval proportional to a product of a time degradation coefficient D of said product in solution and a total volume Vt of the solution at the time of the addition.
